(19) United States
(12) Patent Application Publication
(10) Pub. No.: US 2023/0142180 A1
(43) Pub. Date: May 11, 2023

(54) MASK BLANK, TRANSFER MASK, AND METHOD OF MANUFACTURING SEMICONDUCTOR DEVICE

(71) Applicant: HOYA CORPORATION, Tokyo (JP)

(72) Inventors: Hitoshi MAEDA, Tokyo (JP); Osamu NOZAWA, Tokyo (JP)

(73) Assignee: HOYA CORPORATION, Tokyo (JP)

(21) Appl. No.: 17/966,230

(22) Filed: Oct. 14, 2022

(30) Foreign Application Priority Data
Nov. 10, 2021 (JP) 2021-183510

(51) Int. Cl. G03F 1/22

(52) U.S. Cl. CPC G03F 1/22

(57) ABSTRACT

A mask blank includes a substrate and a thin film formed on the substrate, the thin film including hafnium and oxygen. A total content of hafnium and oxygen of the thin film is 95 atom % or more. An oxygen content of the thin film is 60 atom % or more. An X-ray diffraction profile of a diffraction angle 2θ between 25 degrees and 35 degrees has a maximum diffraction intensity in a diffraction angle 2θ between 28 degrees and 29 degrees, the X-ray diffraction profile being obtained by an X-ray diffraction analysis with an Out-of-Plane measurement with respect to the thin film.

### CROSS-REFERENCE TO RELATED APPLICATIONS

This application claims priority from Japanese Patent Application No. 2021-183510 filed with the Japan Patent Office on Nov. 10, 2021, the entire content of which is hereby incorporated by reference.

### FIELD OF THE DISCLOSURE

The present disclosure relates to a mask blank, a transfer mask, and a method of manufacturing a semiconductor device.

### BACKGROUND

In the manufacturing process of semiconductor devices, a fine pattern is formed using a photolithography method. A number of transfer masks are usually used to form the fine pattern. In order to miniaturize a pattern of a semiconductor device, in addition to miniaturization of a mask pattern formed in a transfer mask, it is necessary to shorten the wavelength of the exposure light source used in photolithography. Recently, shortening of wavelength has been advancing from the use of a KrF excimer laser (wavelength 248 nm) to an ArF excimer laser (wavelength 193 nm) as the exposure light source in the manufacture of semiconductor devices.

As for the types of transfer masks, a half tone phase shift mask is known in addition to a conventional binary mask having a light shielding pattern made of a chromium-based material on a transparent substrate. The half tone phase shift mask includes a mask pattern to be formed on a transparent substrate, the mask pattern configured from a portion that transmits light of an intensity that substantially contributes to exposure (light-transmissive portion) and a portion that transmits light of an intensity that substantially does not contribute to exposure (light-semitransmissive portion). The light-semitransmissive portion shifts the phase of light passing therethrough so that the phase of the light passed therethrough is substantially inverted with respect to the phase of the light transmitted through the light-transmissive portion. As a result, the lights transmitted near the boundary between the light-transmissive portion and the light-semitransmissive portion cancel each other to thereby maintain good contrast at the boundary.

As an example of such transfer masks, Japanese Patent Application Publication H07-209849 discloses a mask blank for a phase shift mask or a phase shift mask in which a half tone phase shift layer on a transparent substrate includes at least one or more layers containing a hafnium compound as a major component.

### SUMMARY

A mask blank includes a substrate and a thin film formed on the substrate, the thin film including hafnium and oxygen. A total content of hafnium and oxygen of the thin film is 95 atom % or more. An oxygen content of the thin film is 60 atom % or more. An X-ray diffraction profile of a diffraction angle 2θ between 25 degrees and 35 degrees has a maximum diffraction intensity in a diffraction angle 2θ between 28 degrees and 29 degrees, the X-ray diffraction profile being obtained by an X-ray diffraction analysis with an Out-of-Plane measurement with respect to the thin film.

### BRIEF DESCRIPTION OF THE DRAWINGS

FIG. 1 is a graph showing the relationship between a diffracted X-ray intensity and a diffraction angle 2θ obtained by an X-ray diffraction analysis with an Out-of-Plane measurement (θ-2θ measurement) on Examples 1 to 3 and Comparative Example of the present disclosure.

FIG. 2 is a graph showing the relationship between the (spatial) frequency and the power spectrum density (PSD) on Examples 1 to 3 and Comparative Example of the present disclosure.

FIG. 3 is a schematic cross-sectional view of a mask blank of the first embodiment.

FIGS. 4A-4G are schematic cross-sectional views showing a manufacturing process of the transfer mask (phase shift mask) of the first embodiment.

FIGS. 5A-5D are schematic cross-sectional views showing a manufacturing process of the mask blank and the transfer mask (binary mask) of the second embodiment.

### EMBODIMENTS FOR CARRYING OUT THE DISCLOSURE

In recent years, with increasing miniaturization and complexity of patterns, there has been a demand for enabling pattern transfer with a higher resolution. In order to realize such high-resolution pattern transfer, it has been considered to apply a configuration containing hafnium and oxygen in a thin film of a mask blank for manufacturing a transfer mask from the viewpoint of enhancing transmittance, etc.

However, when a defect inspection is performed on surfaces of such thin films, pseudo defects are detected, resulting in a problem of an increasing number of defects detected (number of defects detected=number of critical defects+number of pseudo defects). Pseudo defects herein refer to allowable irregularities on a thin film surface that do not affect pattern transfer, but which are misjudged as defects when inspected by a defect inspection apparatus. Critical defects are, for example, defects of 50 nm or more in size. If a large number of such pseudo defects are detected in defect inspection, critical defects that affect pattern transfer may be merged into the large number of pseudo defects, and critical defects that must not be missed may not be found. Failure to detect critical defects in defect inspection causes failure in the subsequent mass production process of semiconductor devices, resulting in unnecessary labor and economic loss.

The present disclosure was made to solve the conventional problem, and an aspect is to provide a mask blank that can restrain detection of pseudo defects on a thin film containing hafnium and oxygen, and that can be used for manufacturing a transfer mask with good optical performance. Further, an aspect of the present disclosure is to provide a transfer mask with good optical performance that can restrain detection of pseudo defects on a thin film containing hafnium and oxygen. Moreover, the present disclosure provides a method of manufacturing a semiconductor device using the transfer mask.

### Means for Solving the Problem

As means for solving the above problems, the present disclosure includes the following configurations.

### (Configuration 1)

A mask blank including:

a substrate; and

a thin film formed on the substrate and including hafnium and oxygen,

in which a total content of hafnium and oxygen of the thin film is 95 atom % or more,

in which an oxygen content of the thin film is 60 atom % or more, and

in which an X-ray diffraction profile of a diffraction angle 2θ between 25 degrees and 35 degrees has a maximum diffraction intensity in a diffraction angle 2θ between 28 degrees and 29 degrees, the X-ray diffraction profile being obtained by an X-ray diffraction analysis with an Out-of-Plane measurement with respect to the thin film.

### (Configuration 2)

The mask blank according to Configuration 1, in which I_Lmax/I_Hmax is 1.5 or more, I_Lmax being a maximum diffraction intensity of a diffraction angle 2θ between 28 degrees and 29 degrees in the X-ray diffraction profile, and I_Hmax being a maximum diffraction intensity of a diffraction angle 2θ between 30 degrees and 32 degrees in the X-ray diffraction profile.

### (Configuration 3)

The mask blank according to Configuration 1 or 2, in which the thin film has crystallinity, and a degree of orientation of m[11-1] is the largest among each of orientations m[11-1], o[111], and m[111] in the thin film.

### (Configuration 4)

The mask blank according to any of Configurations 1 to 3, in which the thin film has crystallinity, and a degree of orientation of o[111] is the smallest among each of orientations m[11-1], o[111], and m[111] in the thin film.

### (Configuration 5)

A transfer mask including:

a substrate; and

a thin film formed on the substrate, the thin film having a transfer pattern and including hafnium and oxygen,

in which a total content of hafnium and oxygen of the thin film is 95 atom % or more,

in which an oxygen content of the thin film is 60 atom % or more, and

in which an X-ray diffraction profile of a diffraction angle 2θ between 25 degrees and 35 degrees has a maximum diffraction intensity in a diffraction angle 2θ between 28 degrees and 29 degrees, the X-ray diffraction profile being obtained by an X-ray diffraction analysis with an Out-of-Plane measurement with respect to the thin film.

### (Configuration 6)

The transfer mask according to Configuration 5, in which I_Lmax/I_Hmax is 1.5 or more, I_Lmax being a maximum diffraction intensity of a diffraction angle 2θ between 28 degrees and 29 degrees in the X-ray diffraction profile, and I_Hmax being a maximum diffraction intensity of a diffraction angle 2θ between 30 degrees and 32 degrees in the X-ray diffraction profile.

### (Configuration 7)

The transfer mask according to Configuration 5 or 6, in which the thin film has crystallinity, and a degree of orientation of m[11-1] is the largest among each of orientations m[11-1], o[111], and m[111] in the thin film.

### (Configuration 8)

The transfer mask according to any of Configurations 5 to 7, in which the thin film has crystallinity, and a degree of orientation of o[111] is the smallest among each of orientations m[11-1], o[111], and m[111] in the thin film.

### (Configuration 9)

A transfer mask including:

a substrate;

a thin film formed on the substrate and including hafnium and oxygen; and

a functional film having a transfer pattern and formed on the substrate,

in which a total content of hafnium and oxygen of the thin film is 95 atom % or more,

in which an oxygen content of the thin film is 60 atom % or more, and

in which an X-ray diffraction profile of a diffraction angle 2θ between 25 degrees and 35 degrees has a maximum diffraction intensity in a diffraction angle 2θ between 28 degrees and 29 degrees, the X-ray diffraction profile being obtained by an X-ray diffraction analysis with an Out-of-Plane measurement with respect to the thin film.

### (Configuration 10)

The transfer mask according to Configuration 9, in which I_Lmax/I_Hmax is 1.5 or more, I_Lmax being a maximum diffraction intensity of a diffraction angle 2θ between 28 degrees and 29 degrees, and I_Hmax being a maximum diffraction intensity of a diffraction angle 2θ between 30 degrees and 32 degrees in the X-ray diffraction profile.

### (Configuration 11)

The transfer mask according to Configuration 9 or 10, in which the thin film has crystallinity, and a degree of orientation of m[11-1] is the largest among each of orientations m[11-1], o[111], and m[111] in the thin film.

### (Configuration 12)

The transfer mask according to any of Configurations 9 to 11, in which the thin film has crystallinity, and a degree of orientation of o[111] is the smallest among each of orientations m[11-1], o[111], and m[111] in the thin film.

### (Configuration 13)

A method of manufacturing a semiconductor device including the step of transferring the transfer pattern to a resist film on a semiconductor substrate by exposure using the transfer mask according to any of Configurations 5 to 12.

The mask blank of the present disclosure having the above configuration includes a substrate and a thin film formed on the substrate and including hafnium and oxygen. The total content of hafnium and oxygen in the thin film is 95 atom % or more. The oxygen content of the thin film is 60 atom % or more. An X-ray diffraction profile of a diffraction angle 2θ between 25 degrees and 35 degrees has the maximum diffraction intensity in a diffraction angle 2θ between 28 degrees and 29 degrees, the X-ray diffraction profile being obtained by an X-ray diffraction analysis with an Out-of-Plane measurement with respect to the thin film. Therefore, it is possible to manufacture a transfer mask that can restrain detection of pseudo defects in a thin film containing hafnium and oxygen, and that has good optical performance. Moreover, in manufacturing a semiconductor device using the transfer mask, a pattern can be transferred to a resist film, etc. on the semiconductor device with excellent precision.

First, the background of the present disclosure is described. The inventors of the present application have diligently studied the configuration of a thin film containing hafnium and oxygen (may hereafter be referred to as “HfO film”), which can restrain the detection of pseudo defects and which exhibits good optical performance. As a result, it was found that even when the compositions of hafnium and oxygen in the HfO film are almost the same, there is a large difference in the detection of pseudo defects on the surface of the HfO film. The inventors found that the power spectrum density (PSD) in a low spatial frequency region at or below a certain value on the HfO film surface to an inspection light source wavelength of a defect inspection apparatus is related to the number of defects detected including pseudo defects on the thin film surface. Specifically, it was found that the smaller the value of the power spectrum density in the low spatial frequency region, the more pseudo defects are reduced.

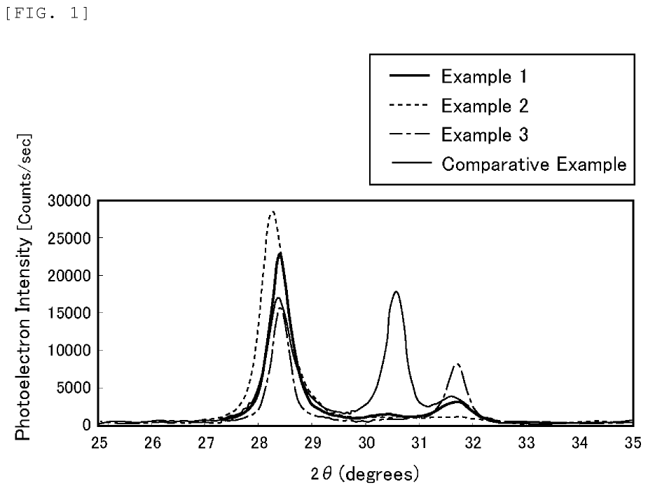

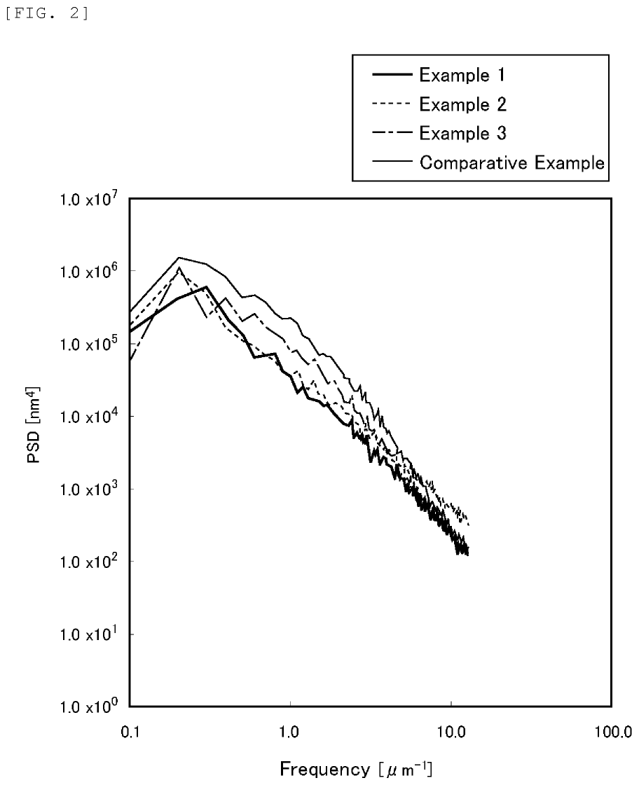

The inventors further diligently studied the composition of the HfO film in which the power spectrum density is reduced in the low spatial frequency region. First, an HfO film formed on a substrate under the conventional film forming conditions, and an HfO film formed on a substrate by adjusting sputtering conditions, etc. were prepared. Next, the inventors analyzed these HfO films by Out-of-Plane measurement (θ-2θ measurement) of an X-ray diffraction method. CuKα ray (wavelength 0.15418 nm) was used as the characteristic X-ray. The same applies hereafter. The HfO film for which the sputtering conditions, etc. were adjusted had the maximum diffraction intensity in a diffraction angle 2θ between 28 degrees and 29 degrees in the range of a diffraction angle 2θ between 25 degrees and 35 degrees; whereas the above was inapplicable to the HfO film formed without adjusting the conventional sputtering conditions, etc. (see FIG. 1). Analysis of the relationship between (spatial) frequency and power spectrum density (PSD) for these HfO films showed that the power spectrum density (PSD) was reduced in the HfO film with adjusted sputtering conditions, etc. in a predetermined low spatial frequency region (e.g., region at or below 5.0 μm⁻¹, more preferably region at or below 1.0 μm⁻¹) compared to the HfO film without the adjustment (see FIG. 2). In other words, the HfO film with adjusted sputtering conditions, etc. was found to have significantly reduced pseudo defects compared to the HfO film without such adjustment.

In light of the above, the inventors found that the detection of pseudo defects can be restrained when an X-ray diffraction profile in a diffraction angle 2θ between 25 degrees and 35 degrees has the maximum diffraction intensity in a diffraction angle 2θ between 28 degrees and 29 degrees in a thin film containing hafnium and oxygen, the X-ray diffraction profile being obtained by an X-ray diffraction analysis with an Out-of-Plane measurement. This does not necessarily apply only to the case where the thin film is crystalline.

The present disclosure has been made based on the knowledge given above. The inference given above is based on the current knowledge of the inventors of the present disclosure and by no means limits the scope of right of the present disclosure.

The embodiments of the present disclosure are explained below based on the drawings. Identical reference numerals are applied to similar components in each drawing.

### First Embodiment

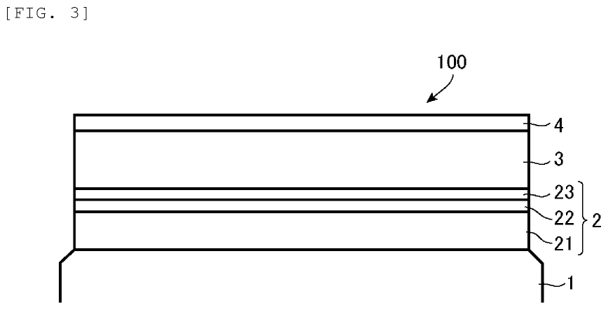

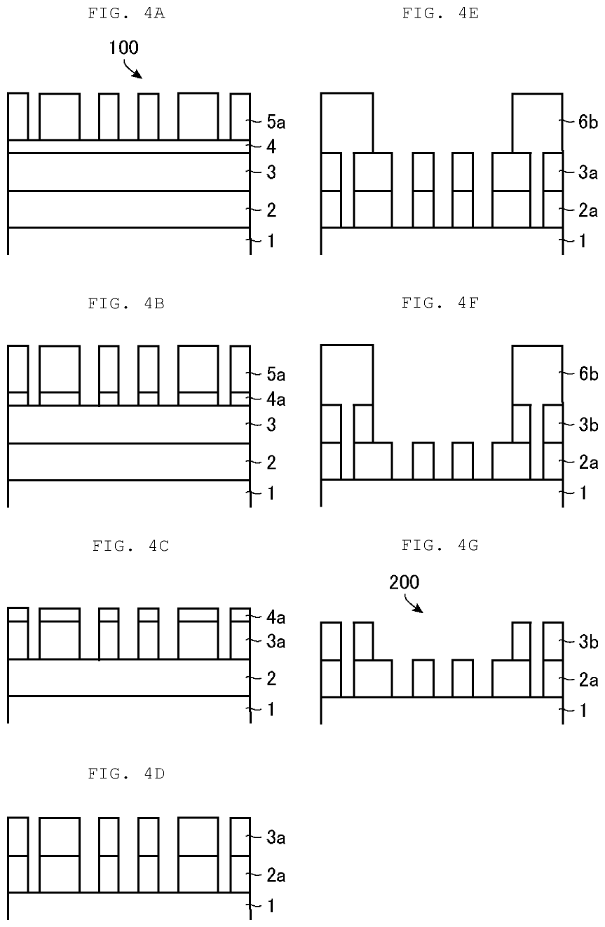

FIG. 3 shows a schematic configuration of a mask blank of the first embodiment. In this embodiment, an explanation is made on the case where a thin film containing hafnium and oxygen is used as an upper layer of a three-layer-structure phase shift film. A mask blank 100 shown in FIG. 3 is for manufacturing a phase shift mask 200 as a transfer mask (FIG. 4G), and has a configuration where a phase shift film 2, a light shielding film 3, and a hard mask film 4 are stacked in this order on one main surface of a transparent substrate 1. The mask blank 100 can have a configuration without the hard mask film 4 as desired. Further, the mask blank 100 can have a configuration where a resist film is stacked on the hard mask film 4 as desired. The detail of major elements of the mask blank 100 is explained below.

### [Transparent Substrate]

The transparent substrate 1 is formed of materials having good transmittance to an exposure light used in an exposure step in lithography. As such materials, synthetic quartz glass, aluminosilicate glass, soda-lime glass, low thermal expansion glass (SiO₂—TiO₂ glass, etc.), and various other glass substrates can be used. Particularly, a substrate using synthetic quartz glass has high transmittance to an ArF excimer laser light (wavelength: about 193 nm), and can be used suitably as the transparent substrate 1 of the mask blank 100.

The exposure step in lithography as used herein refers to an exposure step of lithography using a phase shift mask produced by using the mask blank 100, and the exposure light indicates an ArF excimer laser light (wavelength: 193 nm), unless otherwise specified.

The refractive index of the material forming the transparent substrate 1 to an exposure light is preferably 1.5 or more and 1.6 or less, more preferably 1.52 or more and 1.59 or less, and even more preferably 1.54 or more and 1.58 or less.

### [Phase Shift Film]

To obtain a proper phase shift effect, the phase shift film 2 is preferably adjusted to have a function to generate a phase difference of 150 degrees or more and 210 degrees or less between an exposure light transmitted through the phase shift film 2 and an exposure light transmitted through the transparent substrate 1. The phase difference in the phase shift film 2 is more preferably 155 degrees or more, and even more preferably 160 degrees or more. On the other hand, the phase difference of the phase shift film 2 is more preferably 195 degrees or less, and even more preferably 190 degrees or less.

It is preferable that the transmittance is relatively high to generate a sufficient phase shift effect between an exposure light transmitted through the phase shift film 2 and an exposure light transmitted through the transparent substrate 1. Specifically, the phase shift film 2 preferably has a function to transmit an exposure light at a transmittance of 20% or more, more preferably 30% or more, and further preferably 40%. This is for generating a sufficient phase shift effect between an exposure light transmitted through the interior of the phase shift film 2 and an exposure light transmitted through the transparent substrate 1. Further, the transmittance of the phase shift film 2 to an exposure light is preferably 60% or less, and more preferably 50% or less. This is for controlling the film thickness of the phase shift film 2 within a proper range to secure optical performance. Unless specified, the transmittance in this specification indicates a value which is calculated based on the transmittance of the transparent substrate as a reference value which is 100%.

The phase shift film 2 of this embodiment has a structure where a lowermost layer 21, a lower layer 22, and an upper layer 23 are stacked from the transparent substrate 1 side.

To secure optical performance, the film thickness of the phase shift film 2 is preferably 90 nm or less, more preferably 80 nm or less, and further preferably 70 nm or less. Further, to secure a function to generate a desired phase difference, the film thickness of the phase shift film 2 is preferably 45 nm or more, and more preferably 50 nm or more.

The uppermost layer 23 preferably contains hafnium and oxygen, further preferably consists of hafnium and oxygen. Consisting of hafnium and oxygen herein indicates that a material contains, in addition to hafnium and oxygen, only the elements that may be included in an extremely small amount in the upper layer 23 when the film is formed by a sputtering method. Examples of the elements include noble gas such as helium (He), neon (Ne), argon (Ar), krypton (Kr), and xenon (Xe); hydrogen (H), carbon (C), and nitrogen (N). The same applies to the description on consisting of silicon and oxygen in the lower layer 22 mentioned below. By minimizing the presence of other elements to be bonded to hafnium in the upper layer 23, the ratio of bonding of hafnium and oxygen in the upper layer 23 can be significantly increased.

Therefore, the total content of hafnium and oxygen of the upper layer 23 is preferably 95 atom % or more, more preferably 98 atom % or more, and further preferably 99 atom % or more. Further, the oxygen content of the upper layer 23 is preferably 60 atom % or more, and more preferably 62 atom % or more. Further, the oxygen content of the upper layer 23 is preferably 66 atom % or less where oxygen deficiency is occurring, and more preferably 65 atom % or less, from the viewpoint of etching rate.

Further, it is preferable that the total content of the above-mentioned elements that may be included in an extremely small amount in the upper layer 23 (noble gas, hydrogen, carbon, nitrogen, etc.) is 3 atom % or less.

It is preferable that an X-ray diffraction profile in a diffraction angle 2θ between 25 degrees and 35 degrees has the maximum diffraction intensity in a diffraction angle 2θ between 28 degrees and 29 degrees when the X-ray diffraction profile is obtained by an X-ray diffraction analysis with an Out-of-Plane measurement with respect to the upper layer 23. In other words, when an X-ray diffraction analysis is performed with an Out-of-Plane measurement, the X-ray diffraction profile between 25 degrees and 35 degrees of the upper layer 23 has the maximum peak of the intensity of diffraction ray in a diffraction angle 2θ within the range between 28 degrees and 29 degrees while other peak of an intensity of the diffraction ray is not detected in other ranges (range between 25 degrees and 28 degrees and range between 29 degrees and 35 degrees) or the other peak in the other ranges is sufficiently small to be distinguishable from the maximum peak of the intensity of diffraction ray within the range between 28 degrees and 29 degrees.

Further, I_Lmax/I_Hmax is preferably 1.5 or more, more preferably 1.7 or more, and further preferably 1.9 or more, where I_Lmax is the maximum diffraction intensity of a diffraction angle 2θ between 28 degrees and 29 degrees in the X-ray diffraction profile and I_Hmax is the maximum diffraction intensity of a diffraction angle 2θ between 30 degrees and 32 degrees in the X-ray diffraction profile.

Further, the upper layer 23 preferably has crystallinity with the degree of orientation of m[11-1] being the largest among each of orientations m[11-1], o[111], and m[111].

Moreover, the upper layer 23 preferably has crystallinity with the degree of orientation of o[111] being the smallest among each of orientations m[11-1], o[111], and m[111].

Regarding the above, m[11-1] and m[111] are [11-1] plane and [111] plane in a primitive monoclinic lattice, with diffraction angles 2θ of 28.589 degrees and 31.811 degrees, respectively. Further, o[111] is [111] plane in a primitive orthorhombic lattice, with a diffraction angle 2θ of 30.056 degrees. While m[11-1] is also described as

m[111̅], [Formula 1]

it is described in this specification as m[11-1].

The upper layer 23 preferably has the refractive index n to an exposure light of 3.1 or less, and more preferably 3.0 or less. The upper layer 23 preferably has the refractive index n of 2.5 or more, and more preferably 2.6 or more. On the other hand, the extinction coefficient k of the upper layer 23 to an exposure light is preferably 0.4 or less. This is for enhancing the transmittance of the phase shift film 2 to an exposure light. The extinction coefficient k of the upper layer 23 is preferably 0.05 or more, more preferably 0.1 or more, and even more preferably 0.2 or more. Further, the transmittance of an exposure light of the upper layer 23 can be 20% or more, preferably 30% or more, and further preferably 40% or more.

The thickness of the upper layer 23 is preferably 5 nm or more, and more preferably 6 nm or more, from the viewpoint of chemical resistance and cleaning durability. The thickness of the upper layer 23 is preferably 30 nm or less, more preferably 20 nm or less, and further preferably 15 nm or less, from the viewpoint of optical characteristics.

The lower layer 22 preferably contains silicon and oxygen, and more preferably consists of silicon and oxygen. By minimizing the presence of other elements to be bonded to silicon in the lower layer 22, the ratio of bonding of silicon and oxygen in the lower layer 22 can be significantly increased.

Therefore, the total content of silicon and oxygen in the lower layer 22 is preferably 90 atom % or more, more preferably 95 atom % or more, and further preferably 98 atom % or more. Further, the oxygen content of the lower layer 22 is preferably 50 atom % or more, more preferably 55 atom % or more, and even more preferably 60 atom % or more, from the viewpoint such as an ability to restrain diffusion of silicon to the upper layer 23. Further, it is preferable that the total content of the above-mentioned elements that may be included in an extremely small amount in the lower layer 22 (noble gas, hydrogen, carbon, nitrogen, etc.) is 3 atom % or less.

The lower layer 22 preferably has the refractive index n to an exposure light of 2.0 or less, and more preferably 1.8 or less. The lower layer 22 preferably has the refractive index n of 1.5 or more, and more preferably 1.52 or more. On the other hand, the extinction coefficient k to an exposure light of the lower layer 22 is expected to be less than the lowermost layer 21 and the upper layer 23, preferably less than 0.05, and more preferably 0.02 or less. This is for enhancing the transmittance of the phase shift film 2 to an exposure light.

The thickness of the lower layer 22 is preferably 5 nm or more, and more preferably 7 nm or more, from the viewpoint of chemical resistance and cleaning durability of the side wall of the pattern to be formed. For controlling the film thickness of the phase shift film 2 not to be large, the thickness of the lower layer 22 is preferably 30 nm or less, and more preferably 20 nm or less.

Similar to the upper layer 23, the lowermost layer 21 in this embodiment preferably contains hafnium and oxygen, further preferably consists of hafnium and oxygen. In the case where the lowermost layer 21 is configured to contain hafnium and oxygen, the specific matters regarding preferable total content of hafnium and oxygen, preferable oxygen content, total content of the elements that may be included in an extremely small amount in the lowermost layer 21 (noble gas, hydrogen, carbon, nitrogen, etc.), the refractive index n to an exposure light, and the extinction coefficient k to an exposure light are similar to those of the upper layer 23.

The thickness of the lowermost layer 21 is preferably 5 nm or more, and more preferably 6 nm or more, from the viewpoint of chemical resistance and cleaning durability of the side wall of the pattern to be formed. The thickness of the lowermost layer 21 is preferably 50 nm or less, and more preferably 40 nm or less.

The materials of the lowermost layer 21 are not limited to the materials mentioned above, but may be configured from, in addition to hafnium and oxygen, or in place thereof, other materials (e.g., transition metal silicide-based materials, SiN-based materials, chromium-based materials, tantalum-based materials).

The characteristics (e.g., refractive index n, extinction coefficient k) of the thin film including the phase shift film 2 are not determined only by the composition of the thin film. Film density and crystal state of the thin film are also factors that affect the refractive index n and the extinction coefficient k. Therefore, the conditions in forming the thin film by reactive sputtering are adjusted so that the thin film has desired refractive index n and extinction coefficient k. For allowing the phase shift film 2 to have the refractive index n and extinction coefficient k within the above range, not only a ratio of mixed gas of noble gas and reactive gas (oxygen gas, nitrogen gas, etc.) is adjusted in forming a film by reactive sputtering, but various other adjustments are made upon forming a film by reactive sputtering, such as pressure in a film forming chamber, power applied to a sputtering target, and positional relationship such as distance between a target and the transparent substrate 1. These film forming conditions are unique to film forming apparatuses, and are adjusted properly so that the thin film to be formed has desired characteristics (e.g., refractive index n, extinction coefficient k).

### [Light Shielding Film]

The mask blank 100 may have a light shielding film 3 on the phase shift film 2. In a phase shift mask, an outer peripheral region of a region in which a transfer pattern is formed (transfer pattern forming region) is expected to secure optical density (OD) of a predetermined value or more so that a resist film is not affected by an exposure light that is transmitted through the outer peripheral region when the resist film on a semiconductor wafer is exposure-transferred using an exposure apparatus. The outer peripheral region of the phase shift mask preferably has an OD of 2.8 or more, and more preferably 3.0 or more. As mentioned above, the phase shift film 2 has a function to transmit an exposure light at a predetermined transmittance, and it is difficult to secure an optical density of a predetermined value with the phase shift film 2 alone. Therefore, it is preferable to stack the light shielding film 3 on the phase shift film 2 at the stage of manufacturing the mask blank 100 in order to secure optical density that would otherwise be insufficient. With such a configuration of the mask blank 100, the phase shift mask 200 securing a predetermined value of optical density on the outer peripheral region can be manufactured by removing the light shielding film 3 in the region (basically transfer pattern forming region) where the phase shift effect is to be used, during manufacture of the phase shift mask 200 (see FIGS. 4A-4G).

A single layer structure and a stacked structure of two or more layers are applicable to the light shielding film 3. Further, each layer in the light shielding film 3 of a single layer structure and the light shielding film 3 with a stacked structure of two or more layers may be configured by approximately the same composition in the thickness direction of the film or the layer, or with a composition gradient in the thickness direction of the layer.

The mask blank 100 of the embodiment shown in FIGS. 4A-4G is configured by stacking the light shielding film 3 on the phase shift film 2, without an intervening film. For the light shielding film 3 of this configuration, it is preferable to apply a material having a sufficient etching selectivity to etching gas used in forming a pattern in the phase shift film 2. The light shielding film 3 in this case is preferably formed from a material containing chromium. Materials containing chromium for forming the light shielding film 3 can include, in addition to chromium metal, a material containing chromium and one or more elements selected from oxygen, nitrogen, carbon, boron, and fluorine.

In the case of forming a hard mask film 4, mentioned below, on the light shielding film 3 with a material containing chromium, the light shielding film 3 can be formed of a material containing silicon. Particularly, a material containing a transition metal and silicon has high light shielding performance, which enables reduction of the thickness of the light shielding film 3. The transition metal to be included in the light shielding film 3 includes one metal among molybdenum (Mo), tantalum (Ta), tungsten (W), titanium (Ti), chromium (Cr), nickel (Ni), vanadium (V), zirconium (Zr), ruthenium (Ru), rhodium (Rh), zinc (Zn), niobium (Nb), palladium (Pd), etc., or an alloy of these metals. Metal elements other than the transition metal elements to be included in the light shielding film 3 include aluminum (Al), indium (In), tin (Sn), gallium (Ga), etc.

On the other hand, the light shielding film 3 can have a structure where a layer containing chromium and a layer containing a transition metal and silicon are stacked in this order from the phase shift film 2 side. Specific matters on the materials of the layer containing chromium and the layer containing a transition metal and silicon in this case are similar to the case of the light shielding film 3 described above.

### [Hard Mask Film]

The hard mask film 4 can be provided in contact with a surface of the light shielding film 3. The hard mask film 4 is a film formed of a material having etching durability to etching gas used in etching the light shielding film 3. It is sufficient for the hard mask film 4 to have the film thickness that can function as an etching mask until dry etching for forming a pattern in the light shielding film 3 is completed, and the hard mask film 4 is not basically subjected to limitation of optical characteristics. Therefore, the thickness of the hard mask film 4 can be reduced significantly compared to the thickness of the light shielding film 3.

In the case where the light shielding film 3 is formed of a material containing chromium, the hard mask film 4 is preferably formed of a material containing silicon. Since the hard mask film 4 in this case tends to have low adhesiveness with a resist film of an organic material, it is preferable to treat the surface of the hard mask film 4 with HMDS (Hexamethyldisilazane) to enhance surface adhesiveness. The hard mask film 4 in this case is more preferably formed of SiO₂, SiN, SiON, etc.

Further, in the case where the light shielding film 3 is formed of a material containing chromium, materials containing tantalum are also applicable as materials of the hard mask film 4, in addition to the materials given above. The material containing tantalum in this case includes, in addition to tantalum metal, a material containing tantalum and one or more elements selected from nitrogen, oxygen, boron, and carbon, for example, Ta, TaN, TaO, TaON, TaBN, TaBO, TaBON, TaCN, TaCO, TaCON, TaBCN, TaBOCN, etc. Further, in the case where the light shielding film 3 is formed of a material containing silicon, the hard mask film 4 is preferably formed of the material containing chromium given above.

### [Resist Film]

In the mask blank 100, a resist film of an organic material is preferably formed with a film thickness of 100 nm or less in contact with a surface of the hard mask film 4. In the case of a fine pattern to meet DRAM hp32 nm generation, a SRAF (Sub-Resolution Assist Feature) with 40 nm line width may be provided in a transfer pattern (phase shift pattern) to be formed in the hard mask film 4. However, even in this case, the cross-sectional aspect ratio of the resist pattern can be reduced to 1:2.5 so that collapse and peeling of the resist pattern can be prevented in developing, rinsing, etc. of the resist film. The resist film preferably has a film thickness of 80 nm or less.

Further, in the case of a fine pattern compatible with the DRAM hp32 nm generation, SRAF (Sub-Resolution Assist Feature) having a line width of 40 nm may be provided in a light shielding pattern that is to be formed in the light shielding film 3. However, in this case as well, as described above, the film thickness of the resist film can be controlled to be small as a result of providing the hard mask film 4, and as a consequence, a cross-sectional aspect ratio of the resist pattern formed of the resist film can be reduced to 1:2.5. Therefore, collapse and peeling of the resist pattern can be prevented in developing, rinsing, etc. of the resist film. The resist film preferably has a film thickness of 80 nm or less. The resist film is preferably a resist for electron beam writing exposure, and it is more preferable that the resist is a chemically amplified resist.

The phase shift film 2 of the mask blank 100 of the first embodiment can be patterned by a multistage dry etching process using chlorine-based gas and fluorine-based gas. The lowermost layer 21 and the upper layer 23 are preferably patterned by dry etching using chlorine-based gas, and the lower layer 22 by dry etching using fluorine-based gas. Etching selectivity is extremely high between the lowermost layer 21 and the lower layer 22, and between the lower layer 22 and the upper layer 23. Although not particularly limited, dividing the etching process into multiple stages with respect to the phase shift film 2 with the above characteristics can restrain the effects of side etching and a good pattern cross-sectional shape can be obtained.

While an explanation was made on the first embodiment in which a thin film containing hafnium and oxygen was used as the upper layer of a three-layer structure phase shift film, the lowermost layer can be a thin film containing hafnium and oxygen in addition to the upper layer. As long as optical characteristics such as transmittance are acceptable, the phase shift film may be configured with a single layer structure consisting only of the upper layer described above, or the phase shift film may be configured with the upper layer described above as a multilayer structure with two layers or four or more layers. In the case where the phase shift film is a single layer structure with the upper layer alone, the phase shift film can have high transmittance as described above for the upper layer. This allows the formation of fine patterns in the manufacturing process of the semiconductor device to be performed with higher precision.

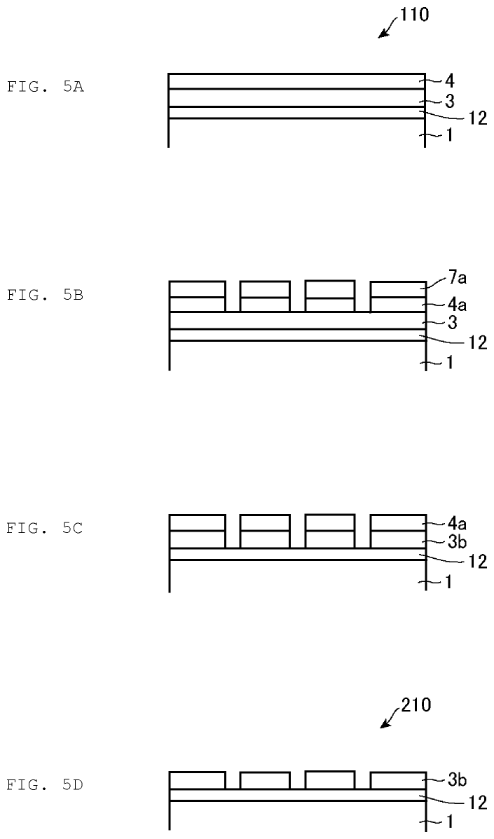

While the mask blank 100 of the first embodiment has the phase shift film 2 in contact with the surface of the transparent substrate 1, it is not limited thereto. For example, a thin film with a single layer structure consisting of the upper layer 23 may be provided, between the transparent substrate 1 and another thin film for pattern formation (light shielding film, phase shift film, etc.), as an etching stopper film 12 to be mentioned below (see FIGS. 5A-5D). This is described below in the second embodiment.

### [Manufacturing Procedure of Mask Blank]

The mask blank 100 of the above configuration is manufactured through the following procedure. First, a transparent substrate 1 is prepared. This transparent substrate 1 includes end surfaces and main surfaces polished into a predetermined surface roughness (e.g., root mean square roughness Sq of 0.2 nm or less in an inner region of a square of fpm side), and thereafter subjected to predetermined cleaning treatment and drying treatment.

Next, a phase shift film 2 is formed on the transparent substrate 1 by the sputtering method, in the order from a lowermost layer 21, a lower layer 22, and an upper layer 23, respectively in the desired thickness given above. While the lowermost layer, the lower layer 22, and the upper layer 23 of the phase shift film 2 are formed by sputtering, any sputtering including DC sputtering, RF sputtering, ion beam sputtering, etc. is applicable. Application of DC sputtering is preferable, considering the film forming rate. In the case where the target has low conductivity, while application of RF sputtering and ion beam sputtering is preferable, application of RF sputtering is more preferable considering the film forming rate.

For the lowermost layer 21 and the upper layer 23 of the phase shift film 2, any of a sputtering target containing hafnium and a sputtering target containing hafnium and oxygen can be applied.

For the lower layer 22 of the phase shift film 2, any of a sputtering target containing silicon and a sputtering target containing silicon and oxygen can be applied.

The surface of the phase shift film 2 is then inspected by a defect inspection apparatus, and defects are repaired as necessary. As described above, in the upper layer 23 of the phase shift film 2, the total content of hafnium and oxygen is 95 atom % or more, and the oxygen content is 60 atom % or more. An X-ray diffraction profile in a diffraction angle 2θ between 25 degrees and 35 degrees has the maximum diffraction intensity in a diffraction angle 2θ between 28 degrees and 29 degrees when the X-ray diffraction profile is obtained by an X-ray diffraction analysis with an Out-of-Plane measurement with respect to the upper layer 23. With the phase shift film 2 having such an upper layer 23, the detection of pseudo defects can be significantly restrained. It is preferable that annealing is properly carried out at a predetermined heating temperature after the phase shift film 2 is formed.

Next, the light shielding film 3 is formed on the phase shift film 2 by the sputtering method. Subsequently, the hard mask film 4 is formed on the light shielding film 3 by the sputtering method. In film formation by the sputtering method, a sputtering target and sputtering gas are used which contain materials forming each of the aforementioned films at a predetermined composition ratio, and moreover, the aforementioned mixed gas of noble gas and reactive gas is used as sputtering gas as necessary. Thereafter, in the case where the mask blank 100 has a resist film, the surface of the hard mask film 4 is subjected to HMDS (Hexamethyldisilazane) treatment as necessary. Next, a resist film is formed by coating methods such as the spin coating method on the surface of the hard mask film 4 to complete the mask blank 100.

Thus, according to the mask blank 100 of the first embodiment, the detection of pseudo defects in the phase shift film 2 containing hafnium and oxygen can be restrained. As a result, the process of distinguishing the pseudo defects and defects that need to be repaired can be omitted or shortened, and defects that need to be repaired can be repaired thoroughly with high precision.

### <Phase Shift Mask and its Manufacturing Method>

FIGS. 4A-4G show a transfer mask (phase shift mask 200) according to an embodiment of the present disclosure manufactured from the mask blank 100 of the above embodiment, and its manufacturing process. As shown in FIG. 4G, the phase shift mask 200 is featured in that a phase shift pattern 2a as a transfer pattern is formed in a phase shift film 2 of the mask blank 100, and that a light shielding pattern 3b having a pattern including a light shielding band is formed in a light shielding film 3. The phase shift mask 200 has a technical feature that is similar to that of the mask blank 100. Matters regarding the transparent substrate 1, the lowermost layer 21, the lower layer 22, and the upper layer 23 of the phase shift film 2, and the light shielding film 3 of the phase shift mask 200 are similar to those of the mask blank 100. The hard mask film 4 is removed during manufacture of the phase shift mask 200.

The method of manufacturing the phase shift mask 200 of the embodiment of the present disclosure uses the mask blank 100 mentioned above, in which the method is featured in including the steps of forming a temporary light shielding pattern 3a in the light shielding film 3 by dry etching; forming a transfer pattern in the phase shift film 2 by dry etching with the temporary light shielding pattern 3a as a mask; and forming a light shielding pattern 3b in the light shielding film 3 by dry etching with a resist film (resist pattern 6b) corresponding to the light shielding pattern as a mask. The method of manufacturing the phase shift mask 200 of the present disclosure is explained below according to the manufacturing steps shown in FIGS. 4A-4G. Explained herein is the method of manufacturing the phase shift mask 200 using the mask blank 100 having the hard mask film 4 stacked on the light shielding film 3. Further, explained herein is the case where a material containing chromium is applied to the light shielding film 3, and where a material containing silicon is applied to the hard mask film 4.

First, a resist film is formed in contact with the hard mask film 4 of the mask blank 100 by the spin coating method. Next, a first pattern corresponding to a transfer pattern (phase shift pattern) to be formed in the phase shift film 2 is written with exposure of an electron beam in the resist film, and a predetermined treatment such as developing is conducted, to thereby form a first resist pattern 5a (see FIG. 4A). Subsequently, dry etching is conducted using fluorine-based gas with the first resist pattern 5a as a mask, and a hard mask pattern 4a is formed in the hard mask film 4 (see FIG. 4B).

Next, after removing the resist pattern 5a, and through predetermined treatments such as cleaning using acid and alkali, dry etching is conducted using mixed gas of chlorine-based gas and oxygen gas with the hard mask pattern 4a as a mask, and a temporary light shielding pattern 3a is formed in the light shielding film 3 (see FIG. 4C). Subsequently, dry etching using chlorine-based gas and dry etching using fluorine-based gas are alternately carried out three times in total with the temporary light shielding pattern 3a as a mask, a phase shift film pattern 2a is formed in the phase shift film 2, and the hard mask pattern 4a is removed (see FIG. 4D). More specifically, the lowermost layer 21 and the upper layer 23 are subjected to dry etching using chlorine-based gas, and the lower layer 22 is subjected to dry etching using fluorine-based gas.

Next, a resist film is formed on the mask blank 100 by the spin coating method. Next, a second pattern corresponding to a pattern to be formed in the light shielding film 3 (light shielding pattern) is written with exposure of an electron beam on the resist film, and predetermined treatments such as developing are conducted, to thereby form a second resist pattern 6b (see FIG. 4E). Subsequently, dry etching is conducted using mixed gas of chlorine-based gas and oxygen gas with the second resist pattern 6b as a mask, and a light shielding pattern 3b is formed in the light shielding film 3 (see FIG. 4F). Further, the second resist pattern 6b is removed, predetermined treatments such as cleaning using acid and alkali are conducted, and the phase shift mask 200 is obtained (see FIG. 4G).

There is no particular limitation to chlorine-based gas to be used in the dry etching described above, as long as Cl is included. Examples of the chlorine-based gas include Cl₂, SiCl₂, CHCl₃, CH₂Cl₂, CCl₄, BCl₃ and the like. Further, the chlorine-based gas used in dry etching of the lowermost layer 21 and the upper layer 23 described above preferably contains boron, and more preferably, contains BCl₃. Particularly, mixed gas of BCl₃ gas and Cl₂ gas is preferred for having relatively high etching rate to hafnium.

The phase shift mask 200 manufactured by the manufacturing method shown in FIGS. 4A-4G is a phase shift mask having a phase shift film 2 (phase shift pattern 2a) having a transfer pattern on the transparent substrate 1. This phase shift mask 200 is formed by patterning the phase shift film 2 of the mask blank 100. Therefore, the characteristics (composition, result of an X-ray diffraction analysis with Out-of-Plane measurement, etc.) of the phase shift film 2 of the phase shift mask 200 are considered the same as those of the phase shift film 2 of the mask blank 100.

By manufacturing the phase shift mask 200 as mentioned above, a phase shift mask 200 having good optical performance can be obtained.

Further, the method of manufacturing the semiconductor device of the first embodiment of the present disclosure is featured in transferring a transfer pattern to a resist film on a semiconductor substrate by exposure using the phase shift mask 200 described above.

Since the phase shift mask 200 and the mask blank 100 of the present disclosure have the effects as described above, when the phase shift mask 200 is set on a mask stage of an exposure apparatus using an ArF excimer laser as an exposure light to transfer a transfer pattern to a resist film on a semiconductor device by exposure, the transfer pattern can be transferred to the resist film on the semiconductor device at a high CD in-plane uniformity. Therefore, in the case where a pattern of this resist film was used as a mask and a lower layer film thereunder was dry etched to form a circuit pattern, a highly precise circuit pattern without short-circuit of wiring and disconnection caused by reduction of CD in-plane uniformity can be formed.

### Second Embodiment

FIG. 5A shows a schematic configuration of a mask blank of the second embodiment. In this embodiment, an explanation is made on the case where a thin film containing hafnium and oxygen is used as an etching stopper film. An example is given herein where an etching stopper film 12 is formed in contact with a transparent substrate 1. A mask blank 110 shown in FIG. 5A is for manufacturing a binary mask 210 as a transfer mask (FIG. 5D), and has a configuration where an etching stopper film 12, a light shielding film 3, and a hard mask film 4 are stacked in this order on one main surface of the transparent substrate 1. While an example is given herein where a film formed on the etching stopper film 12 is the light shielding film 3, another thin film for pattern formation (phase shift film, etc.) can be formed in place of the light shielding film 3. In the case where another thin film for pattern formation is the phase shift film, the resulting transfer mask can function as a phase shift mask. Further, another thin film may be formed between the transparent substrate 1 and the etching stopper film 12.

The etching stopper film 12 has the configurations similar to those of the upper layer 23 of the phase shift film 2 described above in the first embodiment. Namely, in the etching stopper film 12, the total content of hafnium and oxygen is 95 atom % or more, and the oxygen content is 60 atom % or more. An X-ray diffraction profile in a diffraction angle 2θ between 25 degrees and 35 degrees has the maximum diffraction intensity in a diffraction angle 2θ between 28 degrees and 29 degrees when the X-ray diffraction profile is obtained by performing an Out-of-Plane measurement of an X-ray diffraction analysis with respect to the etching stopper film 12. The ratio of the diffraction intensity, I_Lmax/I_Hmax, and the degree of orientation described above are the same as those of the upper layer 23.

It is sufficient if the etching stopper film 12 can secure a function as an etching stopper, but the thickness of the etching stopper film 12 is preferably 3 nm or more and 15 nm or less.

The light shielding film 3 and the hard mask film 4 of this embodiment can have the same configurations as those of the light shielding film 3 and the hard mask film 4 described above in the first embodiment. For example, a material containing silicon can be used for the light shielding film 3 while a material containing chromium can be used for the hard mask film 4. The film thickness of the light shielding film 3 may be greater than that of the first embodiment in order to obtain sufficient light shielding performance with the light shielding film 3 alone. The light shielding film 3 preferably has etching selectivity to the etching stopper film 12.

### [Manufacturing Procedure of Mask Blank]

The mask blank 110 of the above configuration is manufactured by the following procedure. First, a transparent substrate 1 is prepared in the same manner as the first embodiment.

Next, an etching stopper film 12 is formed in a desired thickness on the transparent substrate 1 by the sputtering method. For the etching stopper film 12, any of a sputtering target containing hafnium and a sputtering target containing hafnium and oxygen can be applied.

The surface of the etching stopper film 12 is then inspected by a defect inspection apparatus, and defects are repaired as necessary. As mentioned above, in the etching stopper film 12, the total content of hafnium and oxygen is 95 atom % or more, and the oxygen content is 60 atom % or more. An X-ray diffraction profile in a diffraction angle 2θ between 25 degrees and 35 degrees has the maximum diffraction intensity in a diffraction angle 2θ between 28 degrees and 29 degrees when the X-ray diffraction profile is obtained by an X-ray diffraction analysis with an Out-of-Plane measurement with respect to the etching stopper film 12. With the etching stopper film 12 as described above, the detection of pseudo defects can be significantly restrained.

Next, the light shielding film 3 and the hard mask film 4 described above are formed on the etching stopper film 12 by the sputtering method as described in the first embodiment, the resist film is formed by an application method such as the spin coating method, and the mask blank 110 is completed.

Thus, according to the mask blank 110 of the second embodiment, the detection of pseudo defects in the etching stopper film 12 containing hafnium and oxygen can be restrained. As a result, the process of distinguishing the pseudo defects and defects that need to be repaired can be omitted or shortened, and defects that need to be repaired can be repaired thoroughly with high precision.

### <Binary Mask and its Manufacturing Method>

FIGS. 5A-5D show a binary mask 210 according to an embodiment of the present disclosure manufactured from the mask blank 110 of the above embodiment and its manufacturing process. As shown in FIG. 5D, the binary mask 210 is featured in including an etching stopper film 12 and a functional film (light shielding pattern 3b herein) having a transfer pattern on a transparent substrate 1 of the mask blank 110. The binary mask 210 has the technical features that are similar to those of the mask blank 110. The hard mask film 4 is removed during manufacture of the binary mask 210.

The method of manufacturing the binary mask 210 of the present disclosure is explained below according to the manufacturing steps shown in FIGS. 5A-5D.

First, a resist film is formed in contact with the hard mask film 4 of the mask blank 110 by the spin coating method (not shown). Next, a first pattern corresponding to a transfer pattern (light shielding pattern 3b) to be formed in the light shielding film 3 is written with exposure of an electron beam on the resist film, and predetermined treatments such as developing are conducted, to thereby form a first resist pattern 7a (see FIG. 5B). Subsequently, dry etching is conducted with the first resist pattern 7a as a mask, and a hard mask pattern 4a is formed in the hard mask film 4 (see FIG. 5B).

Next, after removing the resist pattern 7a, and through predetermined treatments such as cleaning using acid and alkali, dry etching is conducted with the hard mask pattern 4a as a mask, and a light shielding pattern 3b is formed in the light shielding film 3 (see FIG. 5C).

Thereafter, the hard mask pattern 4a is removed by dry etching, predetermined treatments such as cleaning are conducted, and the binary mask 210 is obtained (see FIG. 5D). Although not shown, the etching stopper film 12 can be etched with the hard mask pattern 4a and/or the light shielding pattern 3b as a mask to form an etching stopper pattern before the step of FIG. 5D as necessary. In this case, the etching gas is preferably BCl₃ gas.

The binary mask 210 manufactured by the manufacturing method shown in FIGS. 5A-5D includes an etching stopper film 12 (or etching stopper pattern) and a functional film (light shielding pattern 3b) having a transfer pattern on the transparent substrate 1. The binary mask 210 includes the etching stopper film 12 of the mask blank 110. Therefore, the characteristics (composition, result of an X-ray diffraction analysis with Out-of-Plane measurement, etc.) of the etching stopper film 12 of the binary mask 210 are considered the same as those of the etching stopper film 12 of the mask blank 110.

By manufacturing the binary mask 210 as mentioned above, a binary mask 210 having good optical performance can be obtained.

Further, the method of manufacturing the semiconductor device of the second embodiment of the present disclosure is featured in transferring a transfer pattern to a resist film on a semiconductor substrate by exposure using the binary mask 210 described above.

Since the binary mask 210 and the mask blank 110 of the present disclosure have the effects as described above, when the binary mask 210 is set on a mask stage of an exposure apparatus using an ArF excimer laser as an exposure light to transfer a transfer pattern to a resist film on a semiconductor device by exposure, the transfer pattern can be transferred to the resist film on the semiconductor device at a high CD in-plane uniformity. Therefore, in the case where a pattern of this resist film was used as a mask and a lower layer film thereunder was dry etched to form a circuit pattern, a highly precise circuit pattern without short-circuit of wiring and disconnection caused by reduction of CD in-plane uniformity can be formed.

While an explanation was made in this embodiment on the case where a thin film containing hafnium and oxygen was used as a phase shift film and an etching stopper film, it is not limited to thereto. For example, it is also possible to apply a thin film containing hafnium and oxygen having the above-mentioned characteristics as a protective film or an absorber film in an EUV reflective mask blank.

### EXAMPLES

Examples 1 to 3 and Comparative Example 1 are described below to further specifically describe the embodiments of the present disclosure.

### Example 1

### [Manufacture of Mask Blank]

In view of FIG. 3, a transparent substrate 1 formed of a synthetic quartz glass with a size of a main surface of about 152 mm×about 152 mm and a thickness of about 6.35 mm was prepared. End surfaces and main surfaces of the transparent substrate 1 were polished to a predetermined surface roughness (0.2 nm or less Sq), and thereafter subjected to predetermined cleaning treatment and drying treatment. Each optical characteristic of the transparent substrate 1 was measured using a spectroscopic ellipsometer (M-2000D manufactured by J. A. Woollam), and the refractive index was 1.556 and the extinction coefficient was 0.000 to the light of 193 nm wavelength.

Next, the transparent substrate 1 was placed in a single-wafer RF sputtering apparatus, and by sputtering (RF sputtering) alternately using a HfO₂ target and a SiO₂ target with krypton (Kr) gas and argon (Ar) gas as sputtering gas, a phase shift film 2 consisting of a lowermost layer 21 configured from hafnium and oxygen, a lower layer 22 configured from silicon and oxygen, and an upper layer 23 configured from hafnium and oxygen was formed on the transparent substrate 1. Specifically, krypton gas was used as the sputtering gas for forming the lowermost layer 21 and the upper layer 23, with the pressure of 0.13 Pa and 700 W power of RF power source upon sputtering. Further, argon gas was used as the sputtering gas for forming the lower layer 22, with the pressure of 0.04 Pa and 700 W power of RF power source upon sputtering. The thickness of the lowermost layer 21 was 37 nm, the thickness of the lower layer 22 was 11 nm, and the thickness of the upper layer 23 was 8 nm, all having the thickness of 5 nm or more. The thickness of the phase shift film 2 was 56 nm, which was 90 nm or less.

Next, the transparent substrate 1 having the phase shift film 2 formed thereon was subjected to annealing (heat treatment) at 450° C. or more in a high-temperature baking furnace in atmosphere to obtain desired optical characteristics of the phase shift film 2. The transmittance and phase difference of the phase shift film 2 after the heat treatment to the light of 193 nm wavelength were measured using a phase shift measurement apparatus (MPM193 manufactured by Lasertec), and the transmittance was 40.9% and the phase difference was 177.2 degrees. Further, each optical characteristic of the phase shift film 2 was measured using a spectroscopic ellipsometer (M-2000D manufactured by J. A. Woollam), and for the lowermost layer 21 and the upper layer 23 in the light of 193 nm wavelength, the refractive index n was 2.93 and the extinction coefficient k was 0.24; and for the lower layer 22 in the light of 193 nm wavelength, the refractive index n was 1.56 and the extinction coefficient k was 0.00.

Further, the composition of each layer was measured by X-ray photoelectron spectroscopy (XPS), and excluding the interface region of each layer and the interface region between the transparent substrate and the lowermost layer 21, the composition of the lowermost layer 21 was Hf:O=36 atom %:64 atom %, the composition of the lower layer 22 was Si:O=34 atom %%:66 atom %, and the composition of the upper layer 23 was Hf:O=36 atom %:64 atom %. The lowermost layer 21 was the same as the upper layer 23 excluding the film thickness. The total content of hafnium and oxygen of the upper layer 23 of phase shift film 2 was 95 atom % or more, and the oxygen content was 60 atom % or more. The result was the same in the lowermost layer 21.

On a mask blank obtained by forming the phase shift film of Example 1 on another transparent substrate and subjected to annealing as described above, analysis was performed by Out-of-Plane measurement of X-ray diffraction method (θ-2θ measurement). CuKα ray (wavelength 0.15418 nm) was used as the characteristic X-ray. The results of the analysis are shown in FIG. 1. The horizontal axis in FIG. 1 shows a diffraction angle 2θ, and the vertical axis, indicated as photoelectron intensity, is the value obtained by subtracting the value of background intensity from the obtained value of a diffracted X-ray intensity of the mask blank. As the background intensity, the value of diffracted X-ray intensity derived from the transparent substrate multiplied by a normalization constant was used. The normalization constant is the value obtained by dividing, by an average of a diffracted X-ray intensity derived from the transparent substrate in the same range, an average of a diffracted X-ray intensity of the mask blank in the range of 2θ that does not overlap the peak of a diffracted X-ray intensity derived from the phase shift film (20 to 23 degrees in this Example). The same was applied to other Examples and Comparative Example. The lower layer 22 in this example is amorphous, and a diffracted X-ray intensity derived from the lower layer 22 is considered as a small value that is negligible, and further, a diffracted X-ray intensity curve of the lower layer 22 has a broad shape (shape without discernible peaks). Therefore, it was determined that the peaks with high diffracted X-ray intensity in FIG. 1 are derived from the upper layer 23 and the lowermost layer 21. The same applies to other Examples and Comparative Example. As shown in FIG. 1, within a diffraction angle 2θ in the range of 25 to 35 degrees, 28.41 degrees within the range of 28 to 29 degrees had the maximum diffraction intensity.

Further, I_Lmax/I_Hmax was 6.8, which was 1.5 or more, I_Lmax being the maximum diffraction intensity of a diffraction angle 2θ between 28 degrees and 29 degrees and I_Hmax being the maximum diffraction intensity of a diffraction angle 2θ between 30 degrees and 32 degrees.

Then, the degree of orientation at each peak of diffracted X-ray intensity in FIG. 1 was inspected, and it was found that among each of m[11-1], o[111], and m[111] orientations, m[11-1] had the largest degree of orientation and that o[111] had the smallest degree of orientation.

Furthermore, to confirm that the pseudo defects in the phase shift film 2 in Example 1 was reduced, the surface condition of the phase shift film 2 of a mask blank obtained by using another transparent substrate and performing the same processing as described above was measured using a non-contact surface profilometer, and power spectrum density was analyzed. The details are described later.

Next, the transparent substrate 1 having the phase shift film 2 formed thereon was placed in a single-wafer DC sputtering apparatus, and reactive sputtering (DC sputtering) was carried out using a chromium (Cr) target under a mixed gas atmosphere of argon (Ar), carbon dioxide (CO₂), and helium (He). Thus, a light shielding film (CrOC film) 3 formed of chromium, oxygen, and carbon was formed with a film thickness of 53 nm in contact with the phase shift film 2.

Next, the transparent substrate 1 having the light shielding film (CrOC film) 3 formed thereon was subjected to heat treatment. After the heat treatment, a spectrophotometer (Cary4000 manufactured by Agilent Technologies) was used on the transparent substrate 1 having the phase shift film 2 and the light shielding film 3 stacked thereon to measure optical density of the stacked structure of the phase shift film 2 and the light shielding film 3 to an ArF excimer laser light wavelength (about 193 nm), confirming the value of 3.0 or more.

Next, the transparent substrate 1 having the phase shift film 2 and the light shielding film 3 stacked thereon was placed in a single-wafer RF sputtering apparatus, and by RF sputtering using a silicon dioxide (SiO₂) target and argon (Ar) gas as sputtering gas, a hard mask film 4 formed of silicon and oxygen was formed with a thickness of 12 nm on the light shielding film 3. Further, a predetermined cleaning treatment was carried out to form a mask blank 100 of Example 1.

### [Manufacture of Phase Shift Mask]

Next, using the mask blank 100 of Example 1, a half tone phase shift mask 200 of Example 1 was manufactured as shown in FIGS. 4A-4G.

The phase shift pattern 2a of the phase shift mask 200 of Example 1 was observed, resulting in a good phase shift pattern 2a. This phase shift mask 200 was formed by patterning the phase shift film 2 of the mask blank 100 of Example 1. Therefore, the characteristics (composition, results of an X-ray diffraction analysis with Out-of-Plane measurement, etc.) of the phase shift film 2 in the phase shift mask 200 of Example 1 are considered to be the same as those of the phase shift film 2 of the mask blank 100 of Example 1.

### [Evaluation of Pattern Transfer Performance]

On the phase shift mask 200 manufactured by the above procedures, a simulation of a transfer image was made using AIMS193 (manufactured by Carl Zeiss) assuming that an exposure transfer was made on a resist film on a semiconductor device at an exposure light of 193 nm wavelength. The simulated exposure transfer image was inspected, and the design specifications were fully satisfied with high CD in-plane uniformity. It can be considered from this result that a circuit pattern to be finally formed on the semiconductor device can be formed at a high precision when the phase shift mask 200 of Example 1 is set on a mask stage of an exposure apparatus and a resist film on the semiconductor device is subjected to exposure transfer.

### Example 2

### [Manufacture of Mask Blank]

A mask blank of Example 2 was manufactured by the same procedure as that of Example 1, except for the phase shift film. The phase shift film of Example 2 has film forming conditions that are different from those of the phase shift film 2 of Example 1. Specifically, a transparent substrate was placed in a single-wafer RF sputtering apparatus, and by sputtering (RF sputtering) alternately using a HfO₂ target and a SiO₂ target with mixed gas of krypton (Kr) and oxygen as sputtering gas, a phase shift film consisting of a lowermost layer configured from hafnium and oxygen, a lower layer configured from silicon and oxygen, and an upper layer configured from hafnium and oxygen was formed on the transparent substrate. Specifically, mixed gas of krypton gas and oxygen was used as the sputtering gas for forming the lowermost layer 21 and the upper layer 23, with the gas flow ratio of krypton:oxygen=25:1, the pressure of 0.14 Pa, and 700 W power of RF power source upon sputtering. Further, argon gas was used as the sputtering gas for forming the lower layer 22, with the pressure of 0.04 Pa and 700 W power of RF power source upon sputtering. The thickness of the lowermost layer 21 was 37 nm, the thickness of the lower layer 22 was 14 nm, and the thickness of the upper layer 23 was 6 nm, all having the thickness of 5 nm or more. The thickness of the phase shift film 2 was 57 nm, which was 90 nm or less.

Next, the transparent substrate 1 having the phase shift film 2 formed thereon was subjected to annealing (heat treatment) at 450° C. or more in a high-temperature baking furnace in atmosphere to obtain desired optical characteristics of the phase shift film 2. The transmittance and phase difference of the phase shift film 2 after the heat treatment to the light of 193 nm wavelength were measured using a phase shift measurement apparatus (MPM193 manufactured by Lasertec), and the transmittance was 40.4% and the phase difference was 177.0 degrees. Further, each optical characteristic of the phase shift film 2 was measured using a spectroscopic ellipsometer (M-2000D manufactured by J. A. Woollam), and for the lowermost layer 21 and the upper layer 23 in the light of 193 nm wavelength, the refractive index n was 2.94 and the extinction coefficient k was 0.24; and for the lower layer 22 in the light of 193 nm wavelength, the refractive index n was 1.56 and the extinction coefficient k was 0.00.

Further, the composition of each layer was measured by X-ray photoelectron spectroscopy (XPS), and excluding the interface region of each layer and the interface region between the transparent substrate and the lowermost layer 21, the composition of the lowermost layer 21 was Hf:O=35 atom %:65 atom %, the composition of the lower layer 22 was Si:O=34 atom %%:66 atom %, and the composition of the upper layer 23 was Hf:O=35 atom %:65 atom %. The lowermost layer 21 was the same as the upper layer 23 excluding the film thickness. The total content of hafnium and oxygen of the upper layer 23 of phase shift film 2 was 95 atom % or more, and the oxygen content was 60 atom % or more. The result was the same in the lowermost layer 21.

On a mask blank obtained by forming the phase shift film of Example 2 on another transparent substrate and subjected to annealing as described above, analysis was performed by Out-of-Plane measurement of X-ray diffraction method (θ-2θ measurement) in the same manner as Example 1. As shown in FIG. 1, within a diffraction angle 2θ ranging from 25 to 35 degrees, 28.29 degrees within the range of 28 to 29 degrees had the maximum diffraction intensity.

Further, I_Lmax/I_Hmax was 20.7, which was 1.5 or more, I_Lmax being the maximum diffraction intensity of a diffraction angle 2θ between 28 degrees and 29 degrees and that I_Hmax being the maximum diffraction intensity of a diffraction angle 2θ between 30 degrees to 32 degrees.

Then, the degree of orientation at each peak of diffracted X-ray intensity in FIG. 1 was inspected, and it was found that among each of m[11-1], o[111], and m[111] orientations, m[11-1] had the largest degree of orientation and that o[111] had the smallest degree of orientation (degree of orientation of o[111] could not be confirmed).

Further, the power spectrum density was analyzed in the same manner as Example 1. The details are described later.

Next, in the same procedure as Example 1, a light shielding film 3 and a hard mask film 4 were formed, a cleaning process was carried out, and a mask blank 100 of Example 2 was manufactured.

### [Manufacture of Phase Shift Mask]

Next, using the mask blank 100 of Example 2, a half tone phase shift mask 200 of Example 2 was manufactured as shown in FIGS. 4A-4G.

The phase shift pattern 2a of the phase shift mask 200 of Example 2 was observed, resulting in a good phase shift pattern 2a. This phase shift mask 200 was formed by patterning the phase shift film 2 of the mask blank 100 of Example 2. Therefore, the characteristics (composition, results of an X-ray diffraction analysis with out-of-plane measurement, etc.) of the phase shift film 2 in the phase shift mask 200 of Example 2 are considered to be the same as those of the phase shift film 2 in the mask blank 100 of Example 2.

### [Evaluation of Pattern Transfer Performance]

On the phase shift mask 200 manufactured by the above procedures, a simulation of a transfer image was made using AIMS193 (manufactured by Carl Zeiss) assuming that an exposure transfer was made on a resist film on a semiconductor device at an exposure light of 193 nm wavelength. The simulated exposure transfer image was inspected, and the design specifications were fully satisfied with high CD in-plane uniformity. It can be considered from this result that a circuit pattern to be finally formed on the semiconductor device can be formed at a high precision when the phase shift mask 200 of Example 2 is set on a mask stage of an exposure apparatus and a resist film on the semiconductor device is subjected to exposure transfer.

### Example 3

### [Manufacture of Mask Blank]

A mask blank of Example 3 was manufactured by the same procedure as that of Example 1, except for the phase shift film. The phase shift film of Example 3 has film forming conditions that are different from those of the phase shift film 2 of Example 1. Specifically, a transparent substrate was placed in a single-wafer RF sputtering apparatus, and by reactive sputtering (RF sputtering) using a Hf target in a mixed gas atmosphere of krypton (Kr) and oxygen and by sputtering (RF sputtering) using a SiO₂ target with argon (Ar) as sputtering gas, a phase shift film consisting of a lowermost layer configured from hafnium and oxygen, a lower layer configured from silicon and oxygen, and an upper layer configured from hafnium and oxygen was formed on the transparent substrate. Specifically, mixed gas of krypton gas and oxygen was used as the sputtering gas for forming the lowermost layer 21 and the upper layer 23, with the gas flow ratio of krypton:oxygen=5:1, the pressure of 0.14 Pa, and 700 W power of RF power source upon sputtering. Further, argon gas was used as the sputtering gas for forming the lower layer 22, with the pressure of 0.04 Pa and 700 W power of RF power source upon sputtering. The thickness of the lowermost layer 21 was 35 nm, the thickness of the lower layer 22 was 13 nm, and the thickness of the upper layer 23 was 8 nm, all having a thickness of 5 nm or more. The thickness of the phase shift film 2 was 56 nm, which was 90 nm or less.

Next, the transparent substrate 1 having the phase shift film 2 formed thereon was subjected to annealing (heat treatment) at 450° C. or more in a high-temperature baking furnace to in atmosphere obtain desired optical characteristics of the phase shift film 2. The transmittance and phase difference of the phase shift film 2 after the heat treatment to a light of 193 nm wavelength were measured using a phase shift measurement apparatus (MPM193 manufactured by Lasertec), and the transmittance was 40.1% and the phase difference was 175.2 degrees. Further, each optical characteristic of the phase shift film 2 was measured using a spectroscopic ellipsometer (M-2000D manufactured by J. A. Woollam), and for the lowermost layer 21 and the upper layer 23 in the light of 193 nm wavelength, the refractive index n was 2.90 and the extinction coefficient k was 0.22; and for the lower layer 22 in the light of 193 nm wavelength, the refractive index n was 1.56 and the extinction coefficient k was 0.00.

Further, the composition of each layer was measured by X-ray photoelectron spectroscopy (XPS), and excluding the interface region of each layer and the interface region between the transparent substrate and the lowermost layer 21, the composition of the lowermost layer 21 was Hf:O=36 atom %:64 atom %, the composition of the lower layer 22 was Si:O=34 atom %%:66 atom %, and the composition of the upper layer 23 was Hf:O=36 atom %:64 atom %. The lowermost layer 21 was the same as the upper layer 23 excluding the film thickness. The total content of hafnium and oxygen of the upper layer 23 of phase shift film 2 was 95 atom % or more, and the oxygen content was 60 atom % or more. The result was the same in the lowermost layer 21.

On a mask blank obtained by forming the phase shift film of Example 3 on another transparent substrate and subjected to annealing as described above, analysis was performed by Out-of-Plane measurement of X-ray diffraction method (θ-2θ measurement) in the same manner as Example 1. As shown in FIG. 1, within a diffraction angle 2θ ranging from 25 degrees to 35 degrees, 28.4 degrees within the range of 28 degrees to 29 degrees had the maximum diffraction intensity.

Further, I_Lmax/I_Hmax was 1.9, which was 1.5 or more, I_Lmax being the maximum diffraction intensity of a diffraction angle 2θ between 28 degrees to 29 degrees and I_Hmax being the maximum diffraction intensity of a diffraction angle 2θ between 30 degrees to 32 degrees.

As shown in FIG. 1, among each of m[11-1], o[111], and m[111] orientations, m[11-1] had the largest degree of orientation and o[111] had the smallest degree of orientation (degree of orientation of o[111] could not be confirmed).

Further, the power spectrum density was analyzed in the same manner as Example 1. The details are described later.

Next, in the same procedure as Example 1, a light shielding film 3 and a hard mask film 4 were formed, a cleaning process was carried out, and a mask blank 100 of Example 3 was manufactured.

### [Manufacture of Phase Shift Mask]

Next, using the mask blank 100 of Example 3, a half tone phase shift mask 200 of Example 3 was manufactured as shown in FIGS. 4A-4G.

The phase shift pattern 2a of the phase shift mask 200 of Example 3 was observed, resulting in a good phase shift pattern 2a. This phase shift mask 200 is formed by patterning the phase shift film 2 of the mask blank 100 of Example 3. Therefore, the characteristics (composition, results of an X-ray diffraction analysis with Out-of-Plane measurement, etc.) of the phase shift film 2 of the phase shift mask 200 of Example 3 are considered to be the same as those of the phase shift film 2 of the mask blank 100 of Example 3.

### [Evaluation of Pattern Transfer Performance]

On the phase shift mask 200 manufactured by the above procedures, a simulation of a transfer image was made using AIMS193 (manufactured by Carl Zeiss) assuming that an exposure transfer was made on a resist film on a semiconductor device at an exposure light of 193 nm wavelength. The simulated exposure transfer image was inspected, and the design specifications were fully satisfied with high CD in-plane uniformity. It can be considered from this result that a circuit pattern to be finally formed on the semiconductor device can be formed with high precision when the phase shift mask 200 of Example 3 is set on a mask stage of an exposure apparatus and a resist film on the semiconductor device is subjected to exposure transfer.

### Comparative Example 1

### [Manufacture of Mask Blank]

The phase shift film of the mask blank of Comparative Example 1 has film forming conditions that are different from those of the phase shift film 2 of Example 1. Specifically, a transparent substrate was placed in a single-wafer RF sputtering apparatus, and by sputtering (RF sputtering) alternately using a HfO₂ target and a SiO₂ target with argon (Ar) gas as sputtering gas, a phase shift film consisting of a lowermost layer configured from hafnium and oxygen, a lower layer configured from silicon and oxygen, and an upper layer configured from hafnium and oxygen was formed on the transparent substrate. The pressure of the sputtering gas in forming the lowermost layer and the upper layer was 0.04 Pa and power of RF power source upon sputtering was 700 W. Further, the pressure of the sputtering gas in forming the lower layer was 0.04 Pa and power of RF power source upon sputtering was 700 W. The thickness of the lowermost layer was 37 nm, the thickness of the lower layer was 11 nm, and the thickness of the upper layer was 8 nm.

Next, the transparent substrate having the phase shift film formed thereon was subjected to annealing (heat treatment) at 450° C. or more in a high-temperature baking furnace in atmosphere to obtain desired optical characteristics of the phase shift film. The transmittance and phase difference of the phase shift film to the light of 193 nm wavelength were measured using a phase shift measurement apparatus (MPM193 manufactured by Lasertec), and the transmittance was 40.9% and the phase difference was 177.2 degrees. Further, each optical characteristic of the phase shift film was measured using a spectroscopic ellipsometer (M-2000D manufactured by J. A. Woollam), and for the lowermost layer and the upper layer in the light of 193 nm wavelength, the refractive index n was 2.93 and the extinction coefficient k was 0.24; and for the lower layer in the light of 193 nm wavelength, the refractive index n was 1.56 and the extinction coefficient k was 0.00.

Further, the composition of each layer was measured by X-ray photoelectron spectroscopy (XPS), and excluding the interface region of each layer and the interface region between the transparent substrate and the lowermost layer, the composition of the lowermost layer was Hf:O=36 atom %:64 atom %, the composition of the lower layer was Si:O=34 atom %:66 atom %, and the composition of the upper layer was Hf:O=36 atom %:64 atom %. The lowermost layer was the same as the upper layer excluding the film thickness. The total content of hafnium and oxygen of the upper layer 23 of phase shift film 2 was 95 atom % or more, and the oxygen content was 60 atom % or more. The result was the same in the lowermost layer.

On a mask blank obtained by forming the phase shift film of Comparative Example 1 on another transparent substrate and subjected to annealing as described above, analysis was performed by Out-of-Plane measurement of X-ray diffraction method (θ-2θ measurement) in the same manner as Example 1. As shown in FIG. 1, within a diffraction angle 2θ ranging from 25 to 35 degrees, the maximum diffraction intensity was at 30.6 degrees between 30 to 32 degrees, not within the range of 28 degrees to 29 degrees.

Further, I_Lmax/I_Hmax was 0.95, which was not 1.5 or more, I_Lmax being the maximum diffraction intensity of a diffraction angle 2θ between 28 degrees to 29 degrees and I_Hmax being the maximum diffraction intensity of a diffraction angle 2θ between 30 degrees to 32 degrees.

Then, the degree of orientation at each peak of diffracted X-ray intensity in FIG. 1 was inspected, and it was found that among each of m[11-1], o[111], and m[111] orientations, o[111] had the largest degree of orientation. Namely, in Comparative Example 1, the degree of orientation of m[11-1] was not the largest, and the degree of orientation of o[111] was not the smallest.

Further, the power spectrum density was analyzed in the same manner as Example 1. The details are described later.

Next, in the same procedure as Example 1, a light shielding film 3 and a hard mask film 4 were formed, a cleaning process was carried out, and a mask blank 100 of Comparative Example 1 was manufactured.

### [Manufacture of Phase Shift Mask]

Next, using the mask blank 100 of Comparative Example 1, a half tone phase shift mask 200 of Comparative Example 1 was manufactured as shown in FIGS. 4A-4G. This phase shift mask 200 is formed by patterning the phase shift film 2 of the mask blank 100 of Comparative Example 1. Therefore, the characteristics (composition, results of an X-ray diffraction analysis with Out-of-Plane measurement, etc.) of the phase shift film 2 of the phase shift mask 200 of Comparative Example 1 are considered to be the same as those of the phase shift film 2 in the mask blank 100 of Comparative Example 1.

The phase shift pattern 2a of the phase shift mask 200 of Comparative Example 1 was observed, and defects that need to be repaired were found in the phase shift pattern 2a. Therefore, it was found that the phase shift mask 200 of Comparative Example 1 lacked sufficient quality for use in manufacturing semiconductor devices, and needed a defect repairing procedure.

### [Result of Power Spectrum Density (PSD) Analysis]

The results of power spectrum density analysis to the phase shift films 2 of Examples 1 to 3 and Comparative Example 1 are shown in FIG. 2. In the power spectrum density analysis, the surface conditions of the phase shift films 2 of Examples 1 to 3 and Comparative Example 1 were measured using an atomic force microscope (measured region: 10 μm×10 μm; number of pixels: 256×256).

As a result of the power spectrum density analysis, the power spectrum density of the phase shift films 2 of Examples 1 to 3 were less than the power spectrum density of the phase shift film 2 of Comparative Example 1 in the low spatial frequency region between 0.1 μm⁻¹ or more and 1.0 μm⁻¹ or less of spatial frequency as shown in FIG. 2. Further, in this low spatial frequency region, the maximum values of the power spectrum density of Examples 1 to 3 were 6.2×10⁵ nm⁴, 9.9×10⁵ nm⁴, and 1.1×10⁶ nm⁴, respectively, which were 1.5×10⁶ nm⁴ or less, and moreover, 1.2×10⁶ nm⁴ or less. On the other hand, the maximum value of the power spectrum density of the phase shift film 2 of Comparative Example 1 was 1.6×10⁶ nm⁴, exceeding 1.5×10⁶ nm⁴. Thus, in the phase shift films 2 of Examples 1 to 3, the power spectrum density in the low spatial frequency region between 0.1 μm⁻¹ or more and 1.0 μm⁻¹ or less of spatial frequency was significantly reduced compared to the phase shift film 2 of Comparative Example 1. As mentioned above, the smaller the value of the power spectrum density in the low spatial frequency region, the more pseudo defects can be reduced. In other words, it was made clear that the pseudo defects were significantly reduced in Examples 1 to 3 compared to Comparative Example 1.

1. A mask blank comprising:
a substrate; and
a thin film formed on the substrate and including hafnium and oxygen,
wherein a total content of hafnium and oxygen of the thin film is 95 atom % or more,
wherein an oxygen content of the thin film is 60 atom % or more, and
wherein an X-ray diffraction profile of a diffraction angle 2θ between 25 degrees and 35 degrees has a maximum diffraction intensity in a diffraction angle 2θ between 28 degrees and 29 degrees, the X-ray diffraction profile being obtained by an X-ray diffraction analysis with an Out-of-Plane measurement with respect to the thin film.

2. The mask blank according to claim 1, wherein I_Lmax/I_Hmax is 1.5 or more, I_Lmax being a maximum diffraction intensity of a diffraction angle 2θ between 28 degrees and 29 degrees in the X-ray diffraction profile, and I_Hmax being a maximum diffraction intensity of a diffraction angle 2θ between 30 degrees and 32 degrees in the X-ray diffraction profile.

3. The mask blank according to claim 1, wherein the thin film has crystallinity, and a degree of orientation of m[11-1] is the largest among each of orientations m[11-1], o[111], and m[111] in the thin film.

4. The mask blank according to claim 1, wherein the thin film has crystallinity, and a degree of orientation of o[111] is the smallest among each of orientations m[11-1], o[111], and m[111] in the thin film.

5. A transfer mask comprising:
a substrate; and
a thin film formed on the substrate, the thin film having a transfer pattern and including hafnium and oxygen,
wherein a total content of hafnium and oxygen of the thin film is 95 atom % or more,
wherein an oxygen content of the thin film is 60 atom % or more, and
wherein an X-ray diffraction profile of a diffraction angle 2θ between 25 degrees and 35 degrees has a maximum diffraction intensity in a diffraction angle 2θ between 28 degrees and 29 degrees, the X-ray diffraction profile being obtained by an X-ray diffraction analysis with an Out-of-Plane measurement with respect to the thin film.

6. The transfer mask according to claim 5, wherein I_Lmax/I_Hmax is 1.5 or more, I_Lmax being a maximum diffraction intensity of a diffraction angle 2θ between 28 degrees and 29 degrees in the X-ray diffraction profile, and I_Hmax being a maximum diffraction intensity of a diffraction angle 2θ between 30 degrees and 32 degrees in the X-ray diffraction profile.

7. The transfer mask according to claim 5, wherein the thin film has crystallinity, and a degree of orientation of m[11-1] is the largest among each of orientations m[11-1], o[111], and m[111] in the thin film.

8. The transfer mask according to claim 5, wherein the thin film has crystallinity, and a degree of orientation of o[111] is the smallest among each of orientations m[11-1], o[111], and m[111] in the thin film.

9. A transfer mask comprising:
a substrate;
a thin film formed on the substrate and including hafnium and oxygen; and
a functional film having a transfer pattern and formed on the substrate,
wherein a total content of hafnium and oxygen of the thin film is 95 atom % or more,
wherein an oxygen content of the thin film is 60 atom % or more, and
wherein an X-ray diffraction profile of a diffraction angle 2θ between 25 degrees and 35 degrees has a maximum diffraction intensity in a diffraction angle 2θ between 28 degrees and 29 degrees, the X-ray diffraction profile being obtained by an X-ray diffraction analysis with an Out-of-Plane measurement with respect to the thin film.

10. The transfer mask according to claim 9, wherein I_Lmax/I_Hmax is 1.5 or more, I_Lmax being a maximum diffraction intensity of a diffraction angle 2θ between 28 degrees and 29 degrees, and I_Hmax being a maximum diffraction intensity of a diffraction angle 2θ between 30 degrees and 32 degrees in the X-ray diffraction profile.

11. The transfer mask according to claim 9, wherein the thin film has crystallinity, and a degree of orientation of m[11-1] is the largest among each of orientations m[11-1], o[111], and m[111] in the thin film.

12. The transfer mask according to claim 9, wherein the thin film has crystallinity, and a degree of orientation of o[111] is the smallest among each of orientations m[11-1], o[111], and m[111] in the thin film.

13. A method of manufacturing a semiconductor device comprising the step of transferring the transfer pattern to a resist film on a semiconductor substrate by exposure using the transfer mask according to claim 5.

14. A method of manufacturing a semiconductor device comprising the step of transferring the transfer pattern to a resist film on a semiconductor substrate by exposure using the transfer mask according to claim 9.
